(19) United States
(12) Patent Application Publication
(10) Pub. No.: US 2007/0090491 A1
(43) Pub. Date: Apr. 26, 2007

(54) Semiconductor structure with silicon on insulator

(75) Inventors: Jiunn-Ren Hwang, Hsin-Chu City (TW); Wei-Tsun Shiau, Kaohsiung (TW)

Correspondence Address: ARENT FOX PLLC, 1050 CONNECTICUT AVENUE, N.W., SUITE 400, WASHINGTON, DC, 20036, US

(73) Assignee: United Microelectronics Corp.

(21) Appl. No.: 11/583,139

(22) Filed: Oct. 19, 2006

Related U.S. Application Data
(63) Continuation-in-part of application No. 10/407,256, filed on Apr. 7, 2003, now abandoned.

(51) Int. Cl. H01L 29/04

(52) U.S. Cl. 257/628

(57) ABSTRACT

A semiconductor structure with silicon on insulator is disclosed in this present invention. The semiconductor structure at least comprises a first substrate and a second substrate. The crystal orientation of the first substrate is in a first orientation favorable for dicing the semiconductor structure into chips, and the crystal orientation of the second substrate is in a second crystal orientation favorable to the electron carrier mobility. Hence, this invention can efficiently improve the yield of the semiconductor device by reducing the fracture during dicing. Additionally, this invention can improve the performance of the semiconductor device by raising the electron mobility in the substrate.

### CROSS REFERENCE

This application is a continuation-in-part of U.S. patent application Ser. No. 10/407,256, filed on Apr. 7, 2003, entitled Semiconductor Structure With Silicon On Insulator, all of which are incorporated herein by reference and for which priority is claimed under 35 U.S.C. § 120.

### BACKGROUND OF THE INVENTION

1. Field of the Invention

This present invention relates to a semiconductor structure, and more particularly, to a semiconductor structure with silicon on insulator (SOI).

2. Description of the Related Art

In recent years, with the development of the semiconductor manufacture technology, the integration of the semiconductor device is increasing, and the semiconductor element is continuously scaling down. With the above-mentioned development, many new defects are found and have to be overcome.

For example, as the shrinking of metal oxide semiconductor field effect transistor (MOSFET), the channel length of gate is scaling down for higher driving current. The shorter channel of device also causes a higher leakage current. Therefore, new substrates and/or structures, such as silicon on insulator (SOI) and double-gate device, are adapted to improve the performance of the short channel device.

According to the study in the related art, the mobility of electron is related to the crystal orientation of the wafer. When the crystal orientation is in one plane azimuth favorable to the migration of electron, the mobility of electrons in a semiconductor device will be increased. However, the above-mentioned crystal orientation of the wafer is not suitable to the orientation of dicing the wafer into chips. The semiconductor devices on the above-mentioned wafer usually get damage or fracture during dicing, and thus the yield of the semiconductor device is decreased. Particularly, with the scaling down of the semiconductor device, the defects of the semiconductor device during dicing are more and more seriously.

Hence, for improving the electron mobility of the semiconductor device and raising the yield of the semiconductor device, it is an important object to provide a semiconductor structure for increasing the electron migration rate and decreasing the damage of the semiconductor device during dicing.

### SUMMARY OF THE INVENTION

In accordance with the present invention, a semiconductor structure is provided for decreasing the damage of the semiconductor device during dicing by employing a substrate with a crystal orientation, wherein the crystal orientation is favorable to the dicing of the semiconductor structure, so that the yield of the semiconductor device can be improved.

It is another object of this invention to improve the performance of the semiconductor device by utilizing a substrate with a crystal orientation favorable to electron migration.

In accordance with the above-mentioned objects, the invention provides a semiconductor structure at least comprises a first substrate, an insulating layer on the first substrate, and a second substrate on the insulating layer. The semiconductor structure may further comprise at least one semiconductor device formed on the second substrate. The crystal orientations of the first substrate and the second substrate are respectively in a first orientation and a second orientation. The first orientation is favorable for dicing the semiconductor structure into chips, and thus the damage of the semiconductor device during the dicing process can be efficiently reduced. The second orientation is favorable to the electron migration of the semiconductor device, and the electron carrier mobility of the semiconductor can be efficiently improved. Therefore, the design of this prevent invention can efficiently improve the yield and the performance of the semiconductor device.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a cross-sectional view showing a semiconductor structure according to the present invention;

FIG. 2 is a top view illustrating a semiconductor structure 10 according to first embodiment of the present invention;

FIG. 3 is a top view illustrating a semiconductor structure 20 according to third embodiment of the present invention; and

FIG. 4A to FIG. 4C depict the formation of a semiconductor structure according to the present invention.

### DESCRIPTION OF THE PREFERRED EMBODIMENTS

Some sample embodiments of the invention will now be described in greater detail. Nevertheless, it should be recognized that the present invention can be practiced in a wide range of other embodiments besides those explicitly described, and the scope of the present invention is expressly not limited except as specified in the accompanying claims.

Then, the components of the semiconductor devices are not shown to scale. Some dimensions are exaggerated to the related components to provide a more clear description and comprehension of the present invention.

According to the study, the crystal orientation is related with the character of the semiconductor structure. For example, when the crystal orientation of the substrate is in some orientation, the semiconductor structure will have better cleavage and break cleaner along scribe lines, so that the chips do not fracture during dicing. Additionally, when the crystal orientation of the substrate is in some orientation, the mobility of the carriers will be raised. In this invention, a semiconductor structure comprising both of the above-mentioned features is disclosed, so that the yield and the performance of the semiconductor device will be improved.

In the present invention, a semiconductor structure is disclosed herein. The semiconductor structure comprises a first substrate, an insulating layer on the first substrate, and a second substrate on the insulating layer. The crystal orientation of the first substrate is in a first orientation, and the crystal orientation of the second substrate is in a second orientation. The first orientation of the first substrate is favorable for dicing the semiconductor structure into chips. That is, according to this embodiment, the first substrate with the first crystal orientation has better cleavage and breaks cleaner alone scribe lines, so that the semiconductor device do not fracture during dicing the semiconductor structure into chips. Additionally, the second crystal orientation of the second substrate is favorable for raising the electron carrier mobility of the semiconductor device on the second substrate, such as the MOSFET. Hence, not only the damages of the semiconductor device during the dicing can be reduced, but also the electron carrier mobility of the semiconductor device can be raised. Therefore, the yield and the performance of the semiconductor device can be efficiently improved by the design of this embodiment.

FIG. 1 is a cross-sectional view illustrating a semiconductor structure according to the present invention. The semiconductor structure comprises silicon on insulator (SOI) structure. Referring to FIG. 1, the semiconductor structure comprises a first substrate 100, an insulating layer 120 on the first substrate 100, and a second substrate 140 on the insulating layer 120. The first substrate 100 and the second substrate 140 comprise Si. The insulating layer 120 comprises silicon oxide.

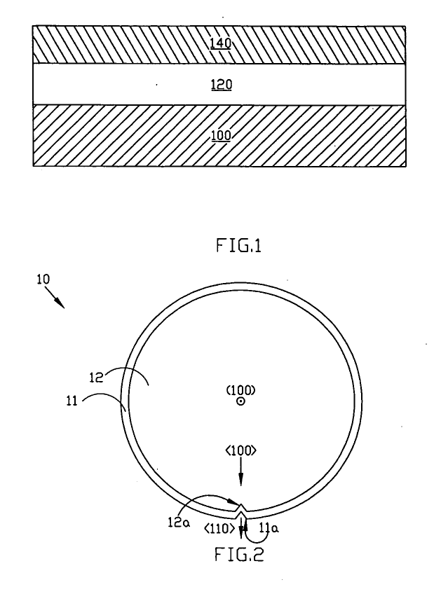

FIG. 2 is a top view illustrating a semiconductor structure 10 according to first embodiment of the present invention. According to this embodiment, the semiconductor structure 10 comprises a first substrate 11, an insulating layer on the first substrate 11, and a second substrate 12 on the insulating layer. The first substrate 11 is a (100) silicon wafer having a notch 11a in a <110>direction, that is, in a first orientation. The first orientation is favorable for dicing the semiconductor structure into chips. In other words, when dicing the semiconductor structure of this embodiment, the semiconductor structure has better cleavage and breaks cleaner along scribe lines. According to the design of this embodiment, the chips do not fracture during dicing. The second substrate 12 is a (100) silicon wafer having a notch 12a in a <100>direction, that is, in a second orientation. In this embodiment, the semiconductor structure 10 further comprises at least one semiconductor device on the second substrate 12, such as MOSFET or others. The second substrate 12 having a notch 12a in a <100>direction is favorable to the electron migration of the semiconductor device, so that the electron carrier mobility of the semiconductor device can be raised. Therefore, according to this embodiment, the performance of the semiconductor device can be improved. According to this embodiment, after the insulating layer is formed on the first substrate 11, the second substrate 12 can be formed on the insulating layer without rotation by a wafer bonding technology.

According to the second embodiment of the present invention, a second semiconductor structure is disclosed herein. The difference between the second embodiment and the first embodiment is that in the second embodiment a second substrate is a (110) silicon wafer having a notch in a <100>direction.

FIG. 3 is a top view illustrating a semiconductor structure 20 according to third embodiment of the present invention. In this embodiment, a first substrate 21 is a (100) silicon wafer having a notch 21a in a <110>direction. A second substrate 22 is also a (100) silicon wafer having a notch 22a in a <110>direction. The second substrate 22 may be rotated in an angle, such as 45 degrees, relative to the first substrate 21, and then bonded on the first substrate 21.

According to above-mentioned embodiment, because the crystal orientation of the first substrate is favorable for dicing the semiconductor structure, the semiconductor structure will break cleaner along scribe lines and the chips of this embodiment do not fracture or get damages during dicing the semiconductor structure into chips. On the other hand, because the crystal orientation of the second substrate is favorable to the electron migration, the electron carrier mobility of the semiconductor device will be raised. Hence, according to this embodiment, the yield and the performance of the semiconductor device can be efficiently improved.

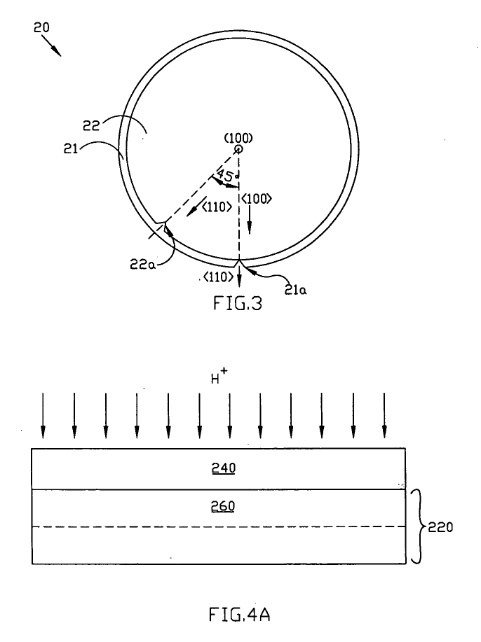

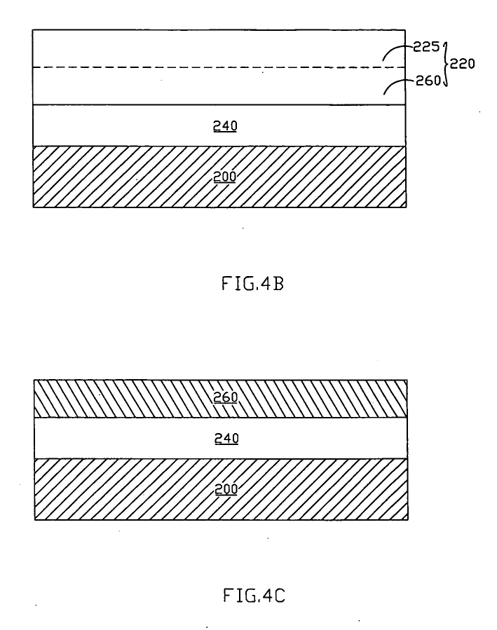

In order to explain this present invention more detailed, the following is the formation of a semiconductor structure. The formation is employed only for explaining this invention, and this invention should not be limited by the following description. The above-mentioned semiconductor structure may comprise a bonding and etch-back silicon on insulator (BESOI) structure. FIG. 4A to FIG. 4C shows the formation of the semiconductor structure of the present invention.

First of all, a first substrate 200 and a second substrate 220 are provided. Referring to FIG. 4A, a silicon oxide layer 240 is formed on the second substrate 220, and an ion implanting is performed on one side of the second substrate 220. The ion employed in the ion implanting comprises hydrogen ion (H⁺). The ion implanting region in the second substrate 220 is marked as 260 in FIG. 4A.

Subsequently, the second substrate 220 can be bonded to the first substrate 200 with the ion-implanted side of the second substrate 220 by a wafer bonding technology. The wafer bonding technology comprises a process performed at a high temperature. In this manner, a semiconductor structure comprising the first substrate 200—silicon oxide layer 240—second substrate 220 SOI structure is formed, as shown in FIG. 4B.

In the first and second embodiment of the present invention, the second substrate can be directly bonded to the first substrate with the ion-implanted side without rotation.

In the third embodiment of the present invention, before bonding the second substrate to the first substrate, the second substrate may be rotated in an angle, such as 45 degrees. Therefore, in the SOI structure of this embodiment, the crystal orientation of the first substrate is favorable for dicing the semiconductor structure into chips, and the crystal orientation of the second substrate is favorable to the electron migration.

Next, a portion of the second substrate 220 is removed by a smart cut technology. Under a high temperature treatment, the region without ion implantation of the second substrate 220, marked as 225 in FIG. 4B, is removed. The above-mentioned smart cut process at least comprises a high temperature treatment for removing the non-ion implantation region 225, and a chemical mechanical polishing (CMP) treatment for leveling the topmost of the second substrate 220. After the smart cut process, the non-implantation region 225 of the second substrate 220 is removed, and a semiconductor structure with SOI as shown in FIG. 4C is formed. The non-implantation region 225 of the second substrate 220 can be recycled and employed as the first substrate 200 or the second substrate 220 at the next time. Therefore, before performing the dicing process, the thickness ratio between the first substrate 200 and the second substrate 220 is about 10:1 to 1000:1. The semiconductor structure will have better cleavage and break cleaner along scribe lines, and the chips do not fracture during dicing.

In the semiconductor structure of the related art, in order to keep the semiconductor device from the fracture or damage during dicing, the semiconductor device is formed on a substrate with the crystal orientation favorable for dicing the semiconductor structure into chips. For example, the above-mentioned substrate which is a (100) silicon wafer having a notch in a <110>direction is not favorable to the electron migration, and the electron carrier mobility of the semiconductor device will be decreased by the substrate.

With the development of the manufacture, in another semiconductor structure of the related art, in order to improve the electron carrier mobility, the semiconductor device can be formed on the substrate with the crystal orientation favorable to the electron migration, such as <100>. In this manner, the electron carrier mobility in the substrate can be raised, and the performance of the semiconductor device can be efficiently improved. However, the crystal orientation of the above-mentioned substrate is not favorable for dicing. When dicing the semiconductor structure into chips, the semiconductor device will get damage or fracture, and the yield of the semiconductor device is decreased.

Comparing with the above-mentioned semiconductor structures in the related art, this invention provides a semiconductor structure comprising two substrates with two crystal orientations. The above-mentioned semiconductor structure may further comprise a SOI structure. The crystal orientation of one substrate of the semiconductor structure is favorable for dicing the semiconductor structure into chips, and the crystal orientation of another substrate of the semiconductor structure is favorable to the electron migration. Therefore, according to the design of this invention, the electron carrier mobility of this prevent invention is higher than the electron carrier mobility in the related art. Moreover, the semiconductor structure of this invention has better cleavage than the semiconductor structure in the related art, and breaks cleaner along scribe lines so that the chips do not fracture during dicing. In one preferred case of this invention, the mobility of the carriers in the substrate of this invention is higher than the mobility of the carriers in the related art by about 70-80%. Hence, according to this invention, the fracture and damage of the semiconductor device during dicing can be reduced, and the electron carrier mobility of the semiconductor device can be increased. That is, this invention can efficiently improve the yield and the performance of the semiconductor device.

According to the preferred embodiments, this invention discloses a semiconductor structure with SOI. In this present invention, the semiconductor structure comprises a first substrate, an insulating layer on the first substrate, and a second substrate on the insulating layer. The semiconductor structure may further comprise at least one semiconductor device on the second substrate. The crystal orientation of the first substrate is favorable for dicing the semiconductor structure into chips. The crystal orientation of the second substrate is favorable to the electron carrier mobility. The second substrate may be formed on the first substrate by a wafer bonding technology. Before bonding to the first substrate, the second substrate may be rotated in an angle. According to this invention, the fracture of the semiconductor device during dicing can be reduced, and the electron carrier mobility of the semiconductor device can be raised. Therefore, the semiconductor structure according to this present invention can efficiently improve the yield and the performance of the semiconductor device.

Although specific embodiments have been illustrated and described, it will be obvious to those skilled in the art that various modifications may be made without departing from what is intended to be limited solely by the appended claims.

What is claimed is:

1. A semiconductor structure, comprising:
a first substrate with a first crystal orientation;
an insulating layer on said first substrate; and
a second substrate with a second crystal orientation on said insulating layer.

2. The structure according to claim 1, wherein said first substrate is a (100) silicon wafer having a first notch in said first crystal orientation, wherein said first crystal orientation is in <110>.

3. The structure according to claim 2, wherein said second substrate is a (100) silicon wafer having a second notch in said second crystal orientation, wherein said second crystal orientation is in <100>.

4. The structure according to claim 2, wherein said second substrate is a (110) silicon wafer having a second notch in said second crystal orientation, wherein said crystal orientation is in <100>.

5. The structure according to claim 1, wherein a thickness ratio of said first substrate to said second substrate is about 10:1 to 1000:1.

6. A semiconductor structure, comprising:
a first substrate with a first crystal orientation;
an insulating layer on said first substrate; and
a second substrate with a second crystal orientation on said insulating layer, wherein said second substrate is rotated in an angle before bonding on said first substrate.

7. The structure according to claim 6, wherein said angle is 45 degrees.

8. The structure according to claim 7, wherein said first substrate is a (100) silicon wafer having a first notch in said first crystal orientation, wherein said crystal orientation is in <110>.

9. The structure according to claim 8, wherein said second substrate is a (100) silicon wafer having a second notch in said first crystal orientation, wherein said crystal orientation is in <110>.

10. The structure according to claim 6, wherein a thickness ratio of said first substrate to said second substrate is about 10:1 to 1000:1.

11. The structure according to claim 6, wherein said insulating layer comprises silicon oxide.

12. A semiconductor structure, wherein said semiconductor structure comprises a bonding and etch-back silicon on insulator structure, comprising:
a first substrate which is a (100) silicon wafer, said first substrate having a first notch in a first crystal orientation, wherein said first crystal orientation is in <110>;
a silicon oxide layer on said first substrate; and
a second substrate with a second crystal orientation on said silicon oxide layer, wherein said second silicon substrate is rotated in an angle and bonded on said first substrate.

13. The structure according to claim 12, wherein said angle is 0 degree.

14. The structure according to claim 13, wherein said second substrate is a (100) silicon wafer having a second notch in said second crystal orientation, wherein said second crystal orientation is in <100>.

15. The structure according to claim 13, wherein said second substrate is a (110) silicon wafer having a second notch in said second crystal orientation, wherein said second crystal orientation is in <100>.

16. The structure according to claim 12, wherein said angle is 45 degrees.

17. The structure according to claim 16, wherein said second substrate is a (100) silicon wafer having a second notch in said second crystal orientation, wherein said second crystal orientation is in <110>.
